(19) United States
(12) Patent Application Publication
(10) Pub. No.: US 2020/0270750 A1
(43) Pub. Date: Aug. 27, 2020

(54) PRECURSOR SOLUTION FOR THIN FILM DEPOSITION AND THIN FILM FORMING METHOD USING SAME

(71) Applicant: SK TRICHEM, Sejong-si (KR)

(72) Inventors: Yong Joo PARK, Daejeon (KR); Han Sol OH, Sejong-si (KR); In Chun HWANG, Sejong-si (KR); Sang Ho KIM, Sejong-si (KR); Chang Sung HONG, Sejong-si (KR); Sang Kyung LEE, Sejong-si (KR)

(21) Appl. No.: 16/762,726

(22) PCT Filed: Nov. 13, 2018
(86) PCT No.: PCT/KR2018/013785

§ 371 Date: May 8, 2020

(30) Foreign Application Priority Data
Nov. 15, 2017 (KR) 10-2017-0152358

(51) Int. Cl. C23C 16/455; C23C 16/34; C23C 16/44

(52) U.S. Cl. CPC C23C 16/45553; C23C 16/4408; C23C 16/34

(57) ABSTRACT

A precursor solution for thin-film deposition including a functional solvent selected from among liquid alkene and liquid alkyne capable of dissolving a metal halide at room temperature and a metal halide dissolved in the functional solvent and existing as a liquid at room temperature, thereby solving problems caused by halogen gas generated in a chamber during a deposition process and improving the uniformity of the thickness of a thin film.

### TECHNICAL FIELD

The present invention relates to a precursor solution for thin-film deposition and a method of forming a thin film using the same, and more particularly to a precursor solution including a metal halide used for atomic layer deposition (ALD) or chemical vapor deposition (CVD) and a method of forming a thin film using the same.

### BACKGROUND ART

As a precursor for atomic layer deposition (ALD) or chemical vapor deposition (CVD), an organometallic compound or metal halide is widely used.

When depositing a titanium metal thin film, examples of the organometallic compound serving as a precursor may include tetradimethylamino-titanium, tetraethylmethylamino-titanium, tetradiethylamino-titanium, and the like. The use of the organometallic compound as the precursor is advantageous in that when depositing a thin film, superior step coverage may be obtained and impurities such as halogen ions are not generated, and thus there is little risk of corrosion in processing, and since it is mostly a liquid precursor, it is convenient to use in processing. However, the material cost thereof is high, thus negating economic benefits, and the organometallic compound has low thermal stability and thus has to be used in the temperature range of 150 to 250° C., and moreover, thin-film characteristics may deteriorate due to organic impurities remaining during deposition of the thin film.

Meanwhile, in order to deposit a titanium metal thin film, examples of the metal halide serving as the precursor may include titanium tetrachloride (TiCl₄), titanium tetraiodide (TiI₄), and the like. Metal halides are inexpensive, thus generating economic benefits, and halides such as TiCl₄ are highly volatile and favorable for deposition, and are currently widely used in various deposition processes because organic impurities are not generated. However, during the deposition process, halogen ions are generated as corrosive gas, which may increase the electrical resistance of the manufactured film due to contamination owing to halogen ions in the thin film, and may damage the underlying film. Furthermore, some metal halides are solid and cannot be applied directly to a deposition process.

With the goal of solving the problems that occur when using a metal halide as the precursor, as disclosed in Korean Patent Nos. 10-0587686, 10-0714269 and the like, it is common to optimize processing conditions so as to prevent damage to the thin film due to halogen ions by purging the precursor and the reaction gas. However, as the thickness, dimension and structure of films manufactured by deposition become complicated these days, merely optimizing processing conditions cannot solve the above problems.

Therefore, Korean Patent Application Publication No. 10-2001-0098415 discloses the addition of a metal halide with an inert gas or additive. Examples of the additive for improving the stability of the halide ligand include alkenes, heterocycles, aryls, alkynes and the like. However, no studies on the specific action of these additives or whether any of them is more effective have been conducted.

Meanwhile, U.S. Pat. No. 8,993,055 discloses a deposition method, which includes contacting a substrate in a reaction space with alternating and sequential pulses of a metal halide as a first metal source chemical and a second source chemical and adding a third source chemical such as acetylene thereto. Here, the third source chemical functions as a deposition-enhancing agent, and the chlorine content in the deposited thin film is decreased 40 times. Although the mechanism therefor is not elucidated, it can be assumed that the supply of acetylene gas into the deposition chamber is effective at suppressing the generation of halogen ions by the metal halide.

Also, U.S. Patent No. 2016-0118262 discloses the addition of acetylene as a third reactant, thereby improving stability in the deposition process.

Also, U.S. Pat. No. 9,409,784 discloses the addition of an alkane, alkene, alkyne or the like as an organic precursor, thereby increasing reactivity upon deposition of a TiCNB layer.

The results of the above conventional techniques lead to speculation that during at least the deposition process, halogen ions generated from the metal halide may be removed before contacting the film by reacting with the triple bond of the acetylene gas.

### DISCLOSURE

### Technical Problem

The present invention has been made keeping in mind the problems encountered in the related art, and an objective of the present invention is to provide a metal halide precursor solution, in which a metal halide is mixed with a functional solvent in order to efficiently remove halogen ions that are generated when using the metal halide as a deposition precursor.

Another objective of the present invention is to provide a precursor solution that is used as a precursor for a deposition process, thus converting halogen gas generated during the deposition process into a non-corrosive volatile liquid, thereby making it possible to solve processing problems caused by halogen ions.

Still another objective of the present invention is to provide a precursor solution capable of functionally removing halogen ions that may be present on the surface of a thin film during a deposition process, thereby improving the properties of the thin film.

Yet another objective of the present invention is to provide a precursor solution in a liquid phase, thus increasing convenience of storage and use during processing, thereby increasing processing efficiency and improving the uniformity of thickness of the thin film.

### Technical Solution

In order to accomplish the above objectives, the present invention provides a precursor solution for thin-film deposition, including a functional solvent selected from among liquid alkene and liquid alkyne capable of dissolving a metal halide at room temperature and a metal halide dissolved in the functional solvent and existing as a liquid at room temperature.

Here, the metal halide may be metal fluoride or metal chloride.

Also, the alkene may be at least one selected from among a linear alkene, a cyclic alkene and a branched alkene, and the alkyne may be at least one selected from among a linear alkyne and a branched alkyne.

Also, the metal halide and the functional solvent may be mixed at a molar ratio of 1:0.01 to 1:20.

In addition, the present invention provides a method of forming a thin film using the above precursor solution for thin-film deposition, including supplying a precursor solution for thin-film deposition in a manner in which a mixture of a metal halide and a functional solvent is supplied into a chamber.

In addition, the present invention provides a method of forming a thin film using the above precursor solution for thin-film deposition, including supplying a precursor solution for thin-film deposition in a manner in which a metal halide and a functional solvent are individually supplied into a chamber at the same time.

In addition, the present invention provides a method of forming a thin film using the above precursor solution for thin-film deposition, including supplying a precursor solution for thin-film deposition in a manner in which a metal halide is supplied into a chamber and then a functional solvent is supplied into the chamber.

Moreover, the method of the present invention may further include, after supplying the precursor solution for thin-film deposition, purging the chamber and additionally supplying a functional solvent into the purged chamber.

### Advantageous Effects

According to the present invention, a precursor solution for thin-film deposition includes a functional solvent therein, thereby efficiently removing halogen gases (HCl, HF, HI, etc.) generated when using a metal halide as a deposition precursor, ultimately solving corrosion problems in processing caused by halogen ions and problems caused by halogen ions that are contained in the thin film.

In addition, the precursor solution can be provided in a liquid phase, thus increasing convenience of storage and use during processing to thereby increase processing efficiency.

In addition, the uniformity of the thickness of the thin film can be increased due to the blocking effect of the functional solvent.

### BRIEF DESCRIPTION OF DRAWINGS

FIG. 1 is a concept view showing a conventional process of manufacturing a TiN thin film;

FIG. 2 is a concept view showing a process of manufacturing a TiN thin film according to the present invention;

FIG. 3 shows NMR data obtained when a mixture of titanium tetrachloride and 1-hexene is allowed to stand for 1 day (a) and 14 days (b) at room temperature;

FIG. 4 shows NMR data obtained when a mixture of titanium tetrachloride and 1-hexene is allowed to stand at room temperature (a), 120° C. (b) and 160° C. (c) for 24 hr;

FIG. 5 shows NMR data obtained before (a) and after (b) a mixture of titanium tetrachloride and 1-hexene is exposed to the ambient atmosphere;

FIG. 6 is a concept view showing a phenomenon of blocking by a functional solvent;

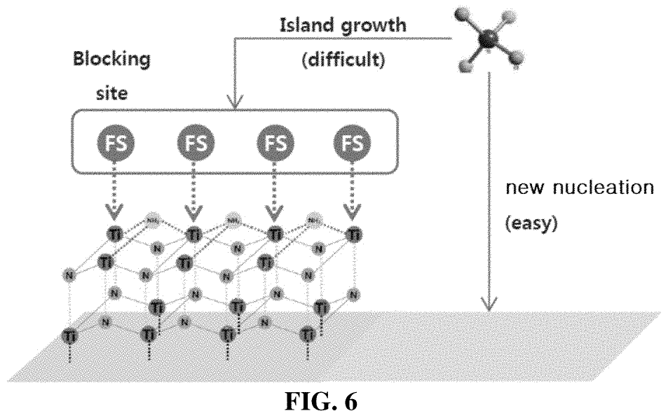

FIG. 7 is a concept view showing a deposition system that performs a deposition process using a mixture of a metal halide and a functional solvent;

FIG. 8 is a concept view showing a deposition system that performs a deposition process by individually supplying a metal halide and a functional solvent into a chamber;

FIG. 9 shows the results of growth per cycle (GPC) measurement depending on the number of deposition cycles in Comparative Example and Examples 1 and 2;

FIG. 10 shows the results of measurement of uniformity of the TiN thin film in Comparative Example and Examples 1 and 2;

FIG. 11 shows the results of observation of the thin film of Comparative Example (a) and Example 1 (b) with an electron microscope; and

FIG. 12 shows the results of ToF-SIMS of chlorine content in the TiN thin film of Comparative Example and Example 1 and 2.

### BEST MODE

Hereinafter, a detailed description will be given of the present invention. The terms or words used in the description and the claims of the present invention are not to be construed limitedly as having typical or dictionary meanings, but should be interpreted as having meanings and concepts of the invention in keeping with the spirit of the invention based on the principle that the inventors can appropriately define the terms in order to describe the invention in the best way.

The present invention pertains to a precursor solution for thin-film deposition, which includes a functional solvent selected from among liquid alkene and liquid alkyne capable of dissolving a metal halide at room temperature and a metal halide dissolved in the functional solvent and existing as a liquid at room temperature.

When a thin film is generally formed, the use of a metal halide as a metal precursor is typical. In this case, strict control of processing conditions is necessary in order to remove halogen ions generated in a chamber for a deposition process.

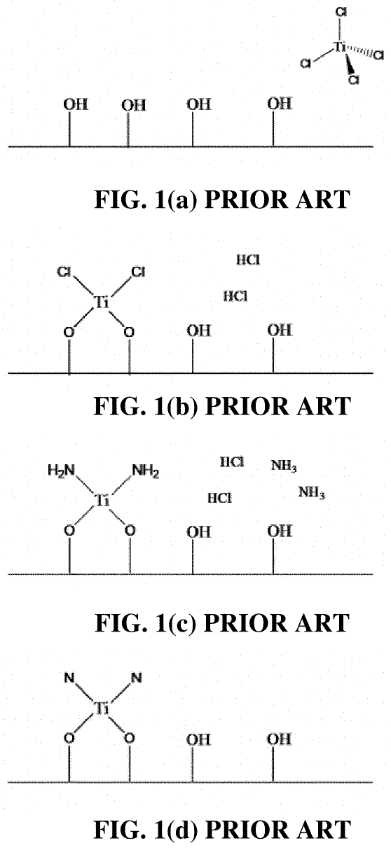

The deposition process may include chemical vapor deposition (CVD), atomic layer deposition (ALD), and the like. FIG. 1 illustrates the formation of a TiN thin film through a conventional deposition process. Specifically, the conventional deposition process includes (a) introducing a titanium tetrachloride (TiCl₄) gas onto a substrate having a reactive group (OH group) formed on the surface thereof, (b) generating hydrogen chloride gas by coupling the reactive group with the titanium compound, (c) performing purging after step (b) to remove most of the hydrogen chloride, and then introducing a reactant NH₃ to substitute chlorine bound to the titanium compound with an amine, and (d) performing purging after step (c) to remove unreacted gas, thus manufacturing a TiN thin film. Here, in order to effectively remove the hydrogen chloride gas generated in step (b) or (c), purge conditions are optimized to thus ensure the electrical properties of the manufactured thin film. Also, the reaction of HCl generated in step (c) with NH₃ may be considered, but cannot be applied to a reaction for removing chlorine ions because a salt precipitate thereof is formed, which is not easy to discharge.

Unlike the conventional deposition process, which takes the approach of optimizing processing conditions, in the present invention, a technique of optimizing the precursor solution by capturing and removing halogen ions generated on the precursor is emphasized. Specifically, the precursor material, namely the metal halide, is mixed with a functional solvent that does not react at room temperature, and the resulting mixture is introduced in the form of gas into a chamber, thereby removing halogen ions generated during processing.

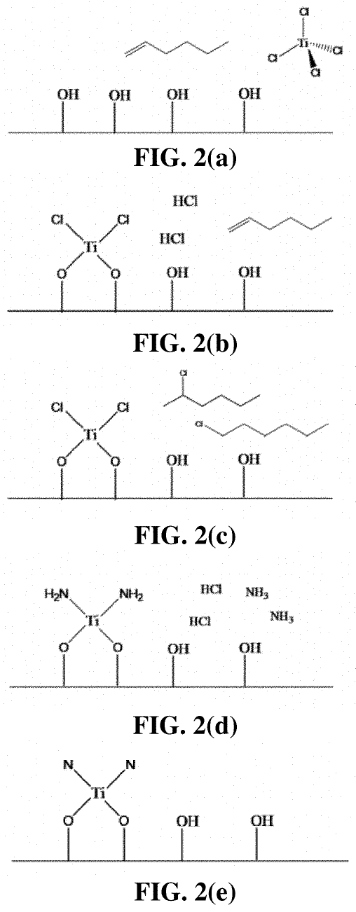

The process of manufacturing the TiN thin film is illustrated in FIG. 2.

Specifically, the TiN thin film is manufactured by (a) introducing a titanium tetrachloride (TiCl₄) gas and a functional solvent, namely n-hexene gas, onto a substrate having a reactive group (OH group) formed on the surface thereof, (b) generating hydrogen chloride gas by coupling the reactive group with the titanium compound, (c) generating hexane chloride by reacting the hydrogen chloride molecule generated in step (b) with n-hexene, (d) removing the gas generated after step (c) through purging and introducing a reactant NH₃ to substitute chlorine bound to the titanium compound with an amine, and (e) removing unreacted gas through purging after step (d). Here, since the hydrogen chloride generated in step (b) is immediately removed by the functional solvent, damage to the thin film due to halogen ions may be significantly alleviated.

Therefore, the metal halide used for the precursor solution for thin-film deposition according to the present invention is a liquid material at room temperature but has to be capable of being vaporized when introduced into the chamber. The functional solvent is a liquid material capable of dissolving the metal halide at room temperature but has to be capable of being vaporized when introduced into the chamber to thus easily react with halogen ions generated in the chamber so as to stabilize the halogen ions. The reason why these materials are liquid at room temperature is that it is easy to store the same in a storage tank before use.

As the metal halide, any material may be used, so long as it is typically useful for the formation of a thin film, and is preferably a material that is liquid at room temperature. Examples of the metal may include Ti, Al, Si, Zn, W, Hf, Zn, Ni and the like, whereas materials, such as WCl₅ and TiI₄, which are solid at room temperature, and WF₆, which is gaseous at room temperature, are difficult to apply but may be used so long as it is able to exist as a liquid at room temperature after dissolution in the functional solvent.

The metal halide, which is liquid at room temperature, may include metal fluoride or metal chloride, examples of which may include titanium tetrachloride (TiCl₄), silicon tetrachloride (SiCl₄), hexachlorodisilane (Si₂Cl₆), tin tetrachloride (SnCl₄), germanium tetrachloride (GeCl₄) and the like.

Moreover, the functional solvent used in the present invention has to be liquid at room temperature, has to be non-reactive with a metal halide, and has to be capable of dissolving the metal halide at room temperature. Only a functional solvent that exhibits all of the above properties is capable of being mixed with a metal halide and selectively reacting with the generated halogen ions without reacting with a metal halide gas even when separately supplied into the chamber.

The functional solvent may include liquid alkene or liquid alkyne, and the hydrocarbon having a double bond or a triple bond may immediately react with highly reactive halogen ions and may thus be stabilized into a halogenated hydrocarbon.

More specifically, the alkene may include at least one selected from among a linear alkene, a cyclic alkene and a branched alkene, and the alkyne may include at least one selected from among a linear alkyne and a branched alkyne.

Also, the specific component of the alkene or alkyne is determined by experimentally measuring the solubility of the metal halide, stability at room temperature, vaporization properties, and the like.

To this end, a mixture of titanium tetrachloride and 1-hexene was prepared, and the stability at room temperature, thermal stability, and chlorine ion removal efficiency were tested.

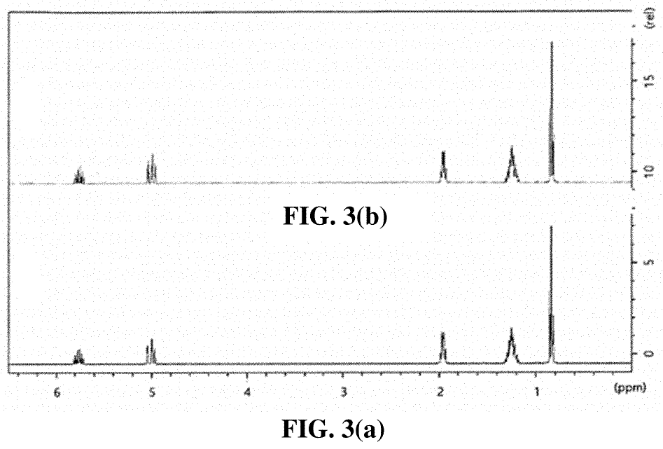

Specifically, when titanium tetrachloride and 1-hexene were mixed at a molar ratio of 1:0.5, there was no change in the NMR spectra on the 1^{st} and 14^{th} days at room temperature, confirming that titanium tetrachloride was stably present in a dissolved state (FIG. 3).

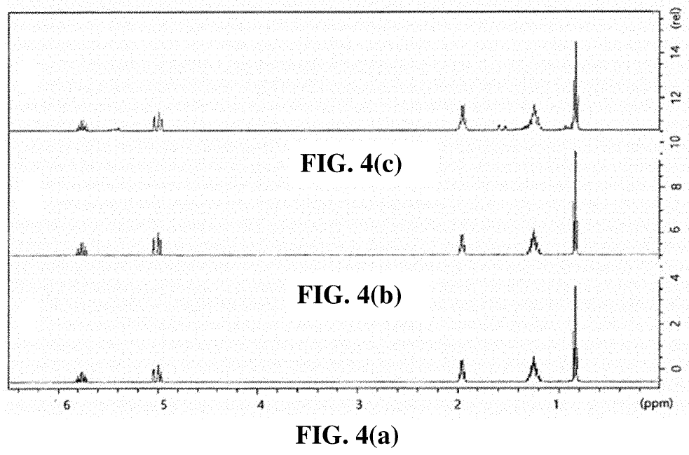

Also, when the NMR spectrum of the mixture of titanium tetrachloride and 1-hexene at a molar ratio of 1:0.5, which was heated from room temperature to a temperature of 120° C. or 160° C. and allowed to stand for 24 hr or more, was observed, the mixture was found not to decompose at 120° C. and to decompose in a small amount at 160° C. Accordingly, when the temperature was higher than 120° C., it was confirmed that decomposition slowly progressed (FIG. 4). However, in the actual deposition process, it was found that there was no influence of thermal decomposition due to exposure to a high temperature for a very short time.

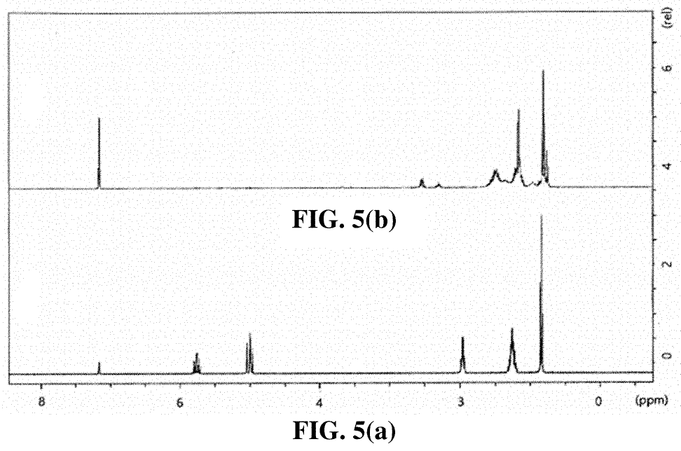

Also, the mixture of titanium tetrachloride and 1-hexene at a molar ratio of 1:2 was exposed to the ambient atmosphere. Through this experiment, titanium tetrachloride was hydrolyzed to thus generate hydrogen chloride, and whether the hydrogen chloride thus generated was able to be stabilized through reaction with 1-hexene was evaluated. As a result thereof, as shown in FIG. 5(b), the peak corresponding to alkyl halide was greatly increased. This showed that the hydrogen chloride generated from titanium tetrachloride was stabilized due to the reaction with 1-hexene.

Various hydrocarbon solvents were tested in order to evaluate the properties thereof for use as the precursor solution for various functional solvent candidates, as shown in Tables 1 and 2 below. Specifically, titanium tetrachloride and a hydrocarbon solvent were mixed at a molar ratio of 1:2 and then introduced into a chamber for ALD or CVD, after which the total chlorine content in the purge gas and the chlorine content of the deposited thin film were measured to evaluate chlorine removal performance.

TABLE 1

| | | | | | After |
|---|---|---|---|---|---|
| | | | | | introduction |
| | Class 1 | Class 2 | Material | Upon mixing | into chamber |
| Alkane | | Chain | Hexane | Neither reactivity nor | No Cl removal |
| | | | | color change | |
| | | Cyclic | Cyclopentane | Neither reactivity nor | No Cl removal |
| | | | | color change | |
| Alkene | 1-ene | Chain | 1-Hexene | Soluble, unreacted at RT, | Cl removal |
| | | | | color change (yellow) | |
| | | | 2-Hexene | Soluble, unreacted at RT | Cl removal |
| | | | 3-Hexene | Soluble, unreacted at RT | Cl removal |
| | | | 1-Heptene | Soluble, unreacted at RT | Cl removal |
| | | | 2-Heptene | Soluble, unreacted at RT | Cl removal |
| | | | 3-Heptene | Soluble, unreacted at RT | Cl removal |
| | | | 1-Nonene | Soluble, unreacted at RT | Cl removal |
| | | | 2-Nonene | Soluble, unreacted at RT | Cl removal |
| | | | 4-Nonene | Soluble, unreacted at RT | Cl removal |
| | | | 1-Decene | Soluble, unreacted at RT | Cl removal |
| | | | 5-Decene | Soluble, unreacted at RT | Cl removal |
| | | | 1-Undecene | Soluble, unreacted at RT | Cl removal |
| | | | 1-Tetradecene | Soluble, unreacted at RT | Cl removal |
| | | Cyclic | Cyclopentene | Soluble, unreacted at RT, | Cl removal |
| | | | | color change (yellow) | |
| | | | 1-Methylcyclopentene | Soluble, unreacted at RT | Cl removal |
| | | | Cyclohexene | Soluble, unreacted at RT | Cl removal |
| | | | Cycloheptene | Soluble, unreacted at RT | Cl removal |
| | | | Cyclooctene | Soluble, unreacted at RT | Cl removal |
| | | Other | 2-Methyl-1-hexene | Soluble, unreacted at RT | Cl removal |
| | | branched | 2-Methyl-2-hexene | Soluble, unreacted at RT | Cl removal |
| | | | 2-Methyl-3-heptene | Soluble, unreacted at RT | Cl removal |
| | | | 3-Methyl-1-hexene | Soluble, unreacted at RT | Cl removal |
| | | | 5 -Methyl-1-hexene | Soluble, unreacted at RT | Cl removal |
| | | | 2-Methyl-1-nonene | Soluble, unreacted at RT | Cl removal |
| | | | 2-Ethyl-1-hexene | Soluble, unreacted at RT | Cl removal |
| | | | 3-Ethyl-2-pentene | Soluble, unreacted at RT | Cl removal |
| | | | 2-Methyl-2-heptene | Soluble, unreacted at RT | Cl removal |
| | | | 2-Methyl-1-undecene | Soluble, unreacted at RT | Cl removal |
| | | | 2,3-Dimethyl-1-butene | Soluble, unreacted at RT | Cl removal |
| | | | 2,3-Dimethyl-1-pentene | Soluble, unreacted at RT | Cl removal |
| | | | 3,3-Dimethyl-1-butene | Soluble, unreacted at RT | Cl removal |
| | | | 2,3-Dimethyl-2-butene | Soluble, unreacted at RT | Cl removal |
| | | | 4,4-Dimethyl-1-pentene | Soluble, unreacted at RT | Cl removal |
| | | | 2,3,4-Trimethyl-1-butene | Soluble, unreacted at RT | Cl removal |
| | | | 2,3,4-Trimethyl-2-pentene | Soluble, unreacted at RT | Cl removal |
| | | | 2,4,4-Trimethyl-2-pentene | Soluble, unreacted at RT | Cl removal |
| | | | 2,2,3-Trimethyl-2-pentene | Soluble, unreacted at RT | Cl removal |
| | | | Methylene cyclopentane | Soluble, unreacted at RT | Cl removal |

TABLE 2

| | | | | | After |
|---|---|---|---|---|---|
| | | | | | introduction |
| HC | Class 1 | Class 2 | Material | Upon mixing | into chamber |
| Alkene | Diene | Chain | 1,3-Pentadiene | Soluble, explosive reaction | — |
| | | | 1,4-Pentadiene | Soluble, slow reaction at RT | Cl removal |
| | | | 1,4-Hexadiene | Soluble, slow reaction at RT | Cl removal |
| | | | 1,7-Octadiene | Soluble, slow reaction at RT | Cl removal |
| | | Cyclic | 1,3-Cyclohexadiene | Soluble, explosive reaction | — |
| | | | 1,4-Cyclohexadiene | Soluble, slow reaction at RT | Cl removal |
| | | | 1-Methyl-1,4-cyclohexadiene | Soluble, slow reaction at RT | Cl removal |
| | | | 1,4-Cyclooctadiene | Soluble, slow reaction at RT | Cl removal |
| | | | 1,3-Cyclooctadiene | Soluble, explosive reaction | — |
| | | | 1,3-Cycloheptadiene | Soluble, explosive reaction | — |
| | | Other | 2,4-Dimethyl-1,3-pentadiene | Soluble, explosive reaction | — |
| | | branched | 2-Methyl-1,5-hexadiene | Soluble, unreacted at RT | Cl removal |
| | | | 3-Methyl-1,4-pentadiene | Soluble, unreacted at RT | Cl removal |
| | | | 2-Methyl-1,4-pentadiene | Soluble, unreacted at RT | Cl removal |
| | Triene | Chain | 1,6-Diphenyl-1,3,5-hexatriene | Soluble, explosive reaction | — |
| | | cyclic | 1,3,5-Hexatriene | Soluble, explosive reaction | — |
| | | | 2,6-Dimethyl-2,4,6-octatriene | Soluble, explosive reaction | — |
| | | | Cycloheptatriene | Soluble, explosive reaction | — |
| | Aromatic | Ring | Toluene | Soluble, no reactivity at RT, | No Cl removal |
| | | | | color change (red) | |
| | | | Xylene | Soluble, unreacted at RT | No Cl removal |
| | | | Ethylbenzene | Soluble, unreacted at RT | No Cl removal |
| | | | Anisole | Slow reaction after | No Cl removal |
| | | | | mixing (solid, black) | |
| Alkyne | 1-yne | Chain | Cyclohexyl acetylene | Soluble, unreacted at RT | Cl removal |
| | | | 1-Pentyne | Soluble, unreacted at RT | Cl removal |
| | | | 1-Hexyne | Soluble, unreacted at RT | Cl removal |
| | | | 2-Hexyne | Soluble, unreacted at RT | Cl removal |
| | | | 3-Hexyne | Soluble, unreacted at RT | Cl removal |
| | | | 1-Heptyne | Soluble, unreacted at RT | Cl removal |
| | | | 1-Octyne | Soluble, unreacted at RT | Cl removal |
| | | | 1-Nonyne | Soluble, unreacted at RT | Cl removal |
| | | | 1-Decyne | Soluble, unreacted at RT | Cl removal |
| | | Other | 5-Methyl-1-hexyne | Soluble, unreacted at RT | Cl removal |
| | | branched | 3,3-Dimethyl-1-bugyne | Soluble, unreacted at RT | Cl removal |
| | | | Cyclohexyl acetylene | Soluble, unreacted at RT | Cl removal |
| | | | 4-Methyl-1-pentyne | Soluble, unreacted at RT | Cl removal |
| | | | Cyclopentyl acetylene | Soluble, unreacted at RT | Cl removal |
| | | Hetero | Acetonitrile | Formation of reaction | — |
| | | | | salt with TiCl₄ | |
| | | | Benzonitrile | Formation of reaction | — |
| | | | | salt with TiCl₄ | |

As is apparent from the results of Tables 1 and 2, in alkenes such as linear alkenes, cyclic alkenes, branched alkenes, linear dienes, cyclic dienes, branched dienes, etc. or in alkynes such as linear alkynes, branched alkynes, etc., titanium tetrachloride was dissolved and mixed at room temperature, and exhibited a chlorine removal effect when introduced into a chamber.

However, the alkanes and halides did not exhibit a chlorine removal effect, indicating that when the material having no reactivity with halogen ions was used as the solvent, the effect of removing halogen ions required in the present invention could not be obtained.

Also, trienes were impossible to use due to excessively high reactivity or low storage stability. The nitrile compound immediately reacted with titanium tetrachloride to form a salt, making it impossible to obtain a stable solution. Among dienes, 1,3-pentadiene, 1,3-cyclohexadiene, 1,3-cyclooctadiene, 1,3-cycloheptadiene, 2,4-dimethyl-1,3-pentadiene, etc. reacted vigorously, making it impossible to obtain a stable solution.

In the present invention, the advantage of introducing the alkane or alkyne functional solvent is not limited only to the removal of halogen ions. Specifically, since it is able to form a it-bond with a thin metal film formed on the surface of the substrate, it may function as a blocking site by adhering to the surface of the metal deposited on the surface of the substrate. Thereby, the probability that new crystal nuclei are formed is higher than the probability that islands are formed on the substrate, so deposition is evenly performed over the entire surface of the substrate. As shown in FIG. 3, since the above functional solvent blocks titanium tetrachloride from further binding onto the titanium atom bound to the substrate surface, it is difficult to form islands, and a new reaction site on the substrate surface is coupled with titanium tetrachloride to create an environment in which crystal nuclei are easily formed. Therefore, it is understood that the functional solvent can be effectively applied to a device structure requiring fine processing and high step coverage because it serves to improve the uniformity of the thickness of the thin film formed on the surface of the substrate.

Moreover, the metal halide and the functional solvent are mixed at a molar ratio of 1:0.01 to 1:20, and preferably a molar ratio of 1:1 to 1:4. If the molar ratio thereof falls out of the above range and thus the amount of the functional solvent is excessively low, chlorine removal performance may deteriorate in the deposition process. On the other hand, if the amount of the functional solvent is excessively high, it is difficult to optimize purge conditions and organic contamination may occur on the thin film.

In addition, the present invention pertains to a method of forming a thin film using the precursor solution for thin-film deposition described above, and may be performed as follows depending on the process of mixing the metal halide and the functional solvent in the precursor solution for thin-film deposition.

In an embodiment, a thin film may be formed by supplying the precursor solution for thin-film deposition in a manner in which a mixture of a metal halide and a functional solvent is supplied into a chamber.

In another embodiment, a thin film may be formed by supplying the precursor solution for thin-film deposition in a manner in which a metal halide and a functional solvent are individually supplied into a chamber at the same time.

In still another embodiment, a thin film may be formed by supplying the precursor solution for thin-film deposition in a manner in which a metal halide is supplied into a chamber and then a functional solvent is supplied into the chamber.

Moreover, in order to introduce the functional solvent again after supplying the precursor solution for thin-film deposition, the chamber may be purged, and the functional solvent may be additionally supplied into the purged chamber, thereby forming a thin film.

These various mixing methods may be selected depending on the type of deposition process.

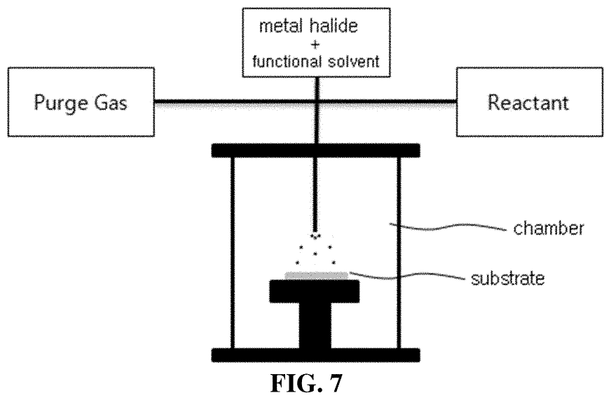

FIG. 7 is a concept view showing a deposition system that performs a deposition process using a mixture of the metal halide and the functional solvent. In such a deposition system, the metal halide and the functional solvent may be mixed to afford a precursor solution for thin-film deposition.

Specifically, the mixture of the metal halide and the functional solvent is stored in a storage tank, and, at the time of a deposition process, may be introduced into a chamber together with purge gas and deposited, after which an oxide film may be formed by the addition of oxygen, etc. or a nitride film may be formed by the addition of nitride, etc.

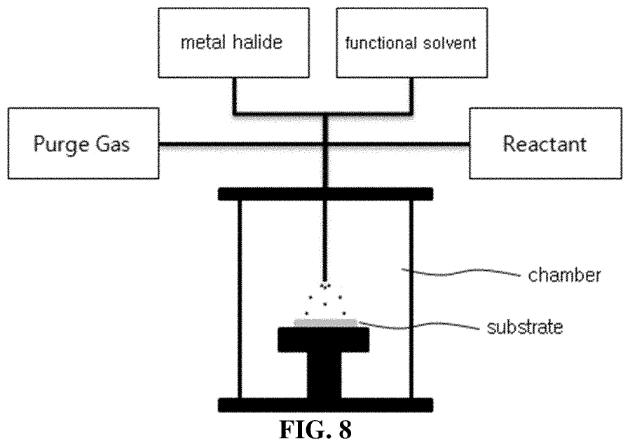

FIG. 8 is a concept view showing a deposition system that performs a deposition process by individually supplying the metal halide and the functional solvent into the chamber. In such a deposition system, the metal halide and the functional solvent are individually stored in storage tanks, and may be simultaneously supplied into the chamber so as to be mixed in the chamber.

Alternatively, in FIG. 8, the metal halide and the functional solvent are individually stored in storage tanks, after which the metal halide may be first supplied into the chamber and purged, and then the functional solvent may be supplied into the chamber, followed by mixing in the chamber.

In FIGS. 7 and 8, since the metal halide and the functional solvent supplied into the chamber are vaporized and mixed at the same time, halide generated in the deposition process may be effectively removed. Moreover, the island formation on the thin film that is deposited is low, and the uniformity of thickness of the film can be improved.

In order to evaluate the effect of application of the precursor solution according to the present invention to the thin-film formation process, the properties of the TiN thin film were measured in Comparative Example, in which typical titanium tetrachloride was used as the precursor, in Example 1, in which titanium tetrachloride dissolved in 1-hexene as the functional solvent was used as the precursor, and in Example 2, in which titanium tetrachloride dissolved in cyclopentene as the functional solvent was used as the precursor. Here, the thickness of the TiN thin film was set to 150 Å.

In Comparative Example 1 and Examples 1 and 2, the thin film was formed through ALD in the precursor deposition temperature range of 400 to 440° C. under the conditions of Table 3 below (in Table 3, FS designates the functional solvent). In order to form a nitride film, ammonia was used as a nitriding reactant, together with the precursor, and argon was used as the carrier gas.

TABLE 3

| | | | | | Flow rate (sccm) | | | | | |
|---|---|---|---|---|---|---|---|---|---|---|
| | Introduction time (sec) | | | | Liquid flow rate (g/min) | | | | Temp. [° C.] | |
| | TiCl₄ | | Nitriding | | | TiCl₄ | | | | Stage |
| | (+FS) | Purge | reactant | Purge | Ar | (+FS) | NH₃ | Purge | MI/MV | [RT] |
| Comparative | 1 | 7 | 3 | 15 | 250 | 0.5 | 500 | 500 + 500 | 100/60 | 400~440 |
| Example | | | | | | | | | | |
| Example 1 | | | | | | | | | | |
| Example 2 | | | | | | | | | | |

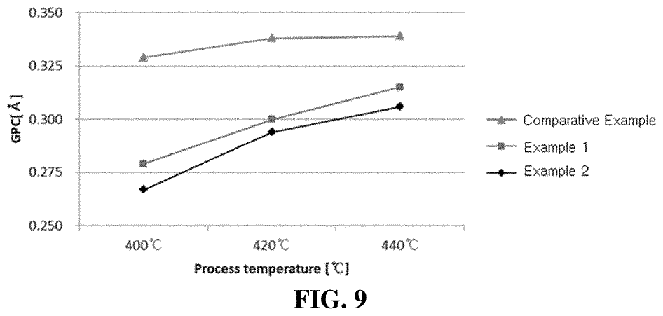

In Comparative Example and Examples 1 and 2, the results of growth per cycle (GPC) measurement depending on the number of deposition cycles are shown in FIG. 9. As is apparent from the results of FIG. 9, in Examples 1 and 2 using the functional solvent of the present invention, GPC was much lower than in Comparative Example. A low GPC when introducing the same amount of precursor means that the growth rate of the thin film in a width direction is slow, indicating that the formation of islands by accumulating the precursor on any one portion was low.

Based on the above analysis results, it can be confirmed that the formation of islands on the TiN films of Examples 1 and 2 was low.

As for GPC depending on changes in temperature, when the deposition temperature was increased to 440° C., GPC was increased overall. However, in Examples 1 and 2, GPC values were lower by 6% and 9%, respectively, than in the Comparative Example, from which it was found that the functional solvent effectively acted even under deposition conditions at a high temperature.

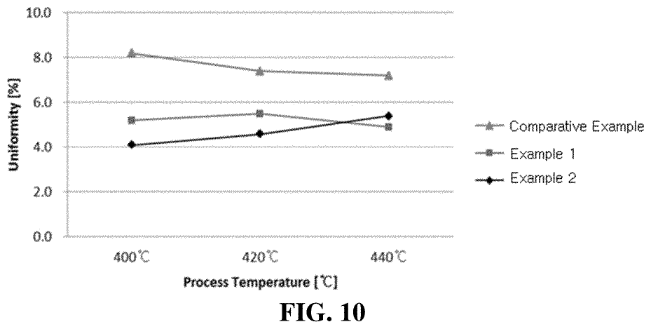

The results of measurement of the uniformity of the TiN thin film of Comparative Example and Examples 1 and 2 are shown in FIG. 10.

As is apparent from the results of FIG. 10, film uniformity was improved in Examples 1 and 2 using the functional solvent of the present invention compared to Comparative Example. In Examples 1 and 2, the formation of islands was low due to low GPC, and the precursor was uniformly deposited on the substrate, from which the effect obtained when introducing the functional solvent of the present invention was confirmed.

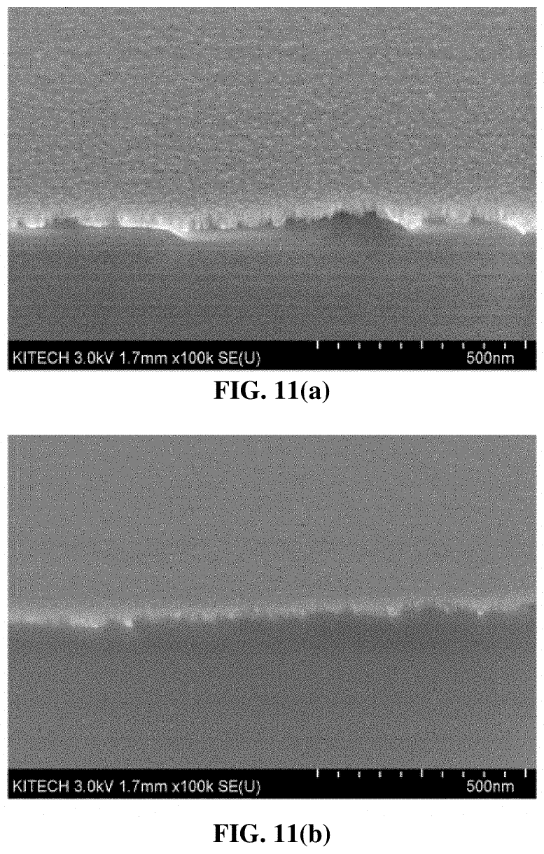

The results of observation of the manufactured thin film using an electron microscope are shown in FIG. 11. As shown in FIG. 11, the surface uniformity of the TiN thin film obtained in Example 1 is superior to that of Comparative Example. This is considered to be due to the application of the functional solvent of the present invention, in which new nucleation is easier than island growth in the film formation process.

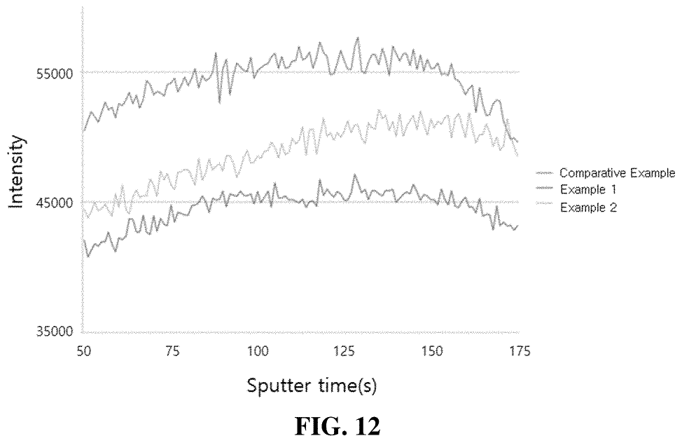

Moreover, in order to evaluate the effect of removing halogen ions due to the use of the functional solvent, the chlorine content in Comparative Example and Examples 1 and 2 was measured. The chlorine content was analyzed using a time-of-flight secondary ion mass spectrometer (ToF-SIMS). The results thereof are shown in FIG. 12.

As is apparent from the results of FIG. 12, the chlorine content was significantly reduced in Examples 1 and 2 compared to Comparative Example, demonstrating the effect of removing the halogen ions through reaction with the double bond or triple bond of the functional solvent and purging.

Therefore, it can be concluded that when the precursor solution according to the present invention is applied to a thin-film deposition process, it is possible to solve processing problems caused by the use of halide and to form a high-quality thin film.

Although the preferred embodiments of the present invention have been disclosed for illustrative purposes, those skilled in the art will appreciate that various modifications and alterations are possible, without departing from the spirit of the present invention. It is also to be understood that such modifications and alterations are incorporated in the scope of the present invention and the accompanying claims.

1. A precursor solution for thin-film deposition, comprising a functional solvent selected from among a liquid alkene and a liquid alkyne capable of dissolving a metal halide at room temperature and a metal halide dissolved in the functional solvent and existing as a liquid at room temperature.

2. The precursor solution of claim 1, wherein the metal halide is metal fluoride or metal chloride.

3. The precursor solution of claim 1, wherein the alkene is at least one selected from among a linear alkene, a cyclic alkene and a branched alkene, and the alkyne is at least one selected from among a linear alkyne and a branched alkyne.

4. The precursor solution of claim 1, wherein the metal halide and the functional solvent are mixed at a molar ratio of 1:0.01 to 1:20.

5. A method of forming a thin film using the precursor solution of claim 1, comprising:
supplying a precursor solution for thin-film deposition in a manner in which a mixture of a metal halide and a functional solvent is supplied into a chamber.

6. A method of forming a thin film using the precursor solution of claim 1, comprising:
supplying a precursor solution for thin-film deposition in a manner in which a metal halide and a functional solvent are individually supplied into a chamber at the same time.

7. A method of forming a thin film using the precursor solution of claim 1, comprising:
supplying a precursor solution for thin-film deposition in a manner in which a metal halide is supplied into a chamber and then a functional solvent is supplied into the chamber.

8. The method of claim 5, further comprising, after supplying the precursor solution for thin-film deposition:
purging the chamber; and
additionally supplying a functional solvent into the purged chamber.

9. The method of claim 6, further comprising, after supplying the precursor solution for thin-film deposition:
purging the chamber; and
additionally supplying a functional solvent into the purged chamber.

10. The method of claim 7, further comprising, after supplying the precursor solution for thin-film deposition:
purging the chamber; and
additionally supplying a functional solvent into the purged chamber.
